(19) United States
(12) Patent Application Publication
(10) Pub. No.: US 2025/0393309 A1
(43) Pub. Date: Dec. 25, 2025

(54) ARRAY SUBSTRATE, DISPLAY PANEL AND DISPLAY DEVICE

(71) Applicant: Xiamen Tianma Optoelectronics Co., Ltd., Xiamen (CN)

(72) Inventors: Pan JIN, Xiamen (CN); Jinmei CHEN, Xiamen (CN); Changgang WU, Xiamen (CN); Zengjie LIN, Xiamen (CN)

(73) Assignee: Xiamen Tianma Optoelectronics Co., Ltd., Xiamen (CN)

(21) Appl. No.: 18/822,278

(22) Filed: Sep. 2, 2024

(30) Foreign Application Priority Data
Jun. 25, 2024 (CN) 202410830935.6

(51) Int. Cl. H01L 27/12; G02F 1/1362; G02F 1/1368

(52) U.S. Cl. CPC H10D 86/60; G02F 1/136286; G02F 1/1368; H10D 86/441

(57) ABSTRACT

The present application relates to an array substrate, a display panel and a display device, in which the array substrate comprises a substrate, routing lines, a pixel driving electrode and a thin film transistor. The routing lines are arranged on the substrate, and the routing lines include a first routing line. The pixel driving electrode is arranged on the substrate. The thin film transistor is arranged on the substrate and connected to the routing lines and the pixel driving electrode each. The thin film transistor comprises an active layer and a gate that are stacked, the gate is electrically connected to the first routing line and comprises a first gate portion, a second gate portion and a connecting line arranged in a same layer.

### CROSS-REFERENCE TO RELATED APPLICATIONS

This application claims priority to Chinese Patent Application No. 202410830935.6, titled “ARRAY SUBSTRATE, DISPLAY PANEL AND DISPLAY DEVICE” and filed on Jun. 25, 2024, which is hereby incorporated by reference in its entirety.

### TECHNICAL FIELD

The present application relates to the field of display technology, and in particular to an array substrate, a display panel and a display device.

### BACKGROUND

With the development of science and technology, the field of display panels has also achieved great progress, and people's requirements for display panels are also increasing. Therefore, how to further improve the display effect of display panels has become a main research direction of major manufacturers.

### SUMMARY

The array substrate, display panel and display device provided in the embodiments of the present application can improve the display effect.

In a first aspect, according to the embodiments of the present application, there is provided an array substrate. The array substrate includes a substrate, routing lines, a pixel driving electrode and a thin film transistor. The routing lines are arranged on the substrate and the routing lines comprise a first routing line. The pixel driving electrode is arranged on the substrate. The thin film transistor is arranged on the substrate and connected to the routing lines and the pixel driving electrode, and the thin film transistor comprises an active layer and a gate that are stacked. The gate is electrically connected to the first routing line. The gate comprises a first gate portion, a second gate portion and a connecting line arranged in a same layer. The connecting line intersects with the first routing line. The first gate portion and the second gate portion are in a strip-shaped. The first gate portion and the second gate portion are connected with each other through the connecting line, and the active layer comprises a strip-shaped main portion. The main portion overlaps the first gate portion and the second gate portion each along a direction perpendicular to the substrate to form two channel regions.

In a second aspect, an embodiment of the present application also provides a display panel including an array substrate. The array substrate includes a substrate, routing lines, a pixel driving electrode and a thin film transistor. The routing lines are arranged on the substrate and the routing lines comprise a first routing line. The pixel driving electrode is arranged on the substrate. The thin film transistor is arranged on the substrate and connected to the routing lines and the pixel driving electrode, and the thin film transistor comprises an active layer and a gate that are stacked. The gate is electrically connected to the first routing line. The gate comprises a first gate portion, a second gate portion and a connecting line arranged in a same layer. The connecting line intersects with the first routing line. The first gate portion and the second gate portion are in a strip-shaped. The first gate portion and the second gate portion are connected with each other through the connecting line, and the active layer comprises a strip-shaped main portion. The main portion overlaps the first gate portion and the second gate portion each along a direction perpendicular to the substrate to form two channel regions.

In a third aspect, an embodiment of the present application also provides a display device including a display panel. The display panel includes an array substrate. The array substrate includes a substrate, routing lines, a pixel driving electrode and a thin film transistor.

The routing lines are arranged on the substrate and the routing lines comprise a first routing line. The pixel driving electrode is arranged on the substrate. The thin film transistor is arranged on the substrate and connected to the routing lines and the pixel driving electrode, and the thin film transistor comprises an active layer and a gate that are stacked. The gate is electrically connected to the first routing line. The gate comprises a first gate portion, a second gate portion and a connecting line arranged in a same layer. The connecting line intersects with the first routing line. The first gate portion and the second gate portion are in a strip-shaped. The first gate portion and the second gate portion are connected with each other through the connecting line, and the active layer comprises a strip-shaped main portion. The main portion overlaps the first gate portion and the second gate portion each along a direction perpendicular to the substrate to form two channel regions.

### BRIEF DESCRIPTION OF THE DRAWINGS

The features, advantages and technical effects of the exemplary embodiments in the present application will be described below with reference to the drawings.

FIG. 1 is a schematic structural diagram of an array substrate according to some embodiments of the present application;

FIG. 2 is a schematic structural cross-sectional view of A-A in FIG. 1;

FIG. 3 is a schematic structural cross-sectional view of B-B in FIG. 1;

FIG. 4 is a schematic structural diagram of another array substrate according to some embodiments of the present application;

FIG. 5 is a schematic structural diagram of a display panel according to some embodiments of the present application;

FIG. 6 is a schematic structural diagram of another array substrate according to some embodiments of the present application;

FIG. 7 is a schematic structural diagram of another array substrate according to some embodiments of the present application;

FIG. 8 is a schematic structural diagram of another array substrate according to some embodiments of the present application;

FIG. 9 is a schematic structural diagram of another array substrate according to some embodiments of the present application;

FIG. 10 is a schematic structural diagram of another array substrate according to some embodiments of the present application;

FIG. 11 is a schematic structural diagram of another array substrate according to some embodiments of the present application;

FIG. 12 is a schematic structural diagram of another array substrate according to some embodiments of the present application;

FIG. 13 is a schematic structural cross-sectional view of an array substrate according to some embodiments of the present application;

FIG. 14 is a schematic structural cross-sectional view of another array substrate according to some embodiments of the present application; and

FIG. 15 is a schematic structural diagram of a display device according to some embodiments of the present application.

### DETAILED DESCRIPTION

The features and exemplary embodiments of various aspects of the present application will be described in detail below. In order to make the purpose, technical solutions and advantages of the present application clearer, the present application will be further described in detail below in conjunction with the drawings and specific embodiments. It should be understood that the specific embodiments described herein are intended only to explain the present application, rather than to limit the present application. For those skilled in the art, the present application may be implemented without some of these specific details. The following description of the embodiments is only to provide a better understanding of the present application by showing examples of the present application.

It should be noted that in this application, relational terms such as first and second are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, the elements defined by the sentence “include . . . ” do not exclude the existence of other identical elements in the process, method, article or device including the elements.

At present, in the display panel, the array substrate provides a driving circuit for the light-emitting layer in the display panel, and the driving circuit includes a thin film transistor, which generally includes an active layer, a gate, a source, and a drain. As the display panel process becomes more mature, higher requirements are put forward for the display effect of the display panel, such as a more delicate display screen.

As the requirements for display effects increase, that is, the requirements for the resolution of the display panel also increase. The design of high PPI (Pixel Per Inch) and high aperture ratio means a smaller size of the thin film transistor. While reducing the size of the thin film transistor, a smaller leakage current is also required to meet the predetermined number of scan lines scanned within a predetermined time. However, in the related art, it is impossible to reduce the size of the thin film transistor while reducing the leakage current requirements, resulting in an increase in abnormal problems in the display screen while the resolution of the display panel increases.

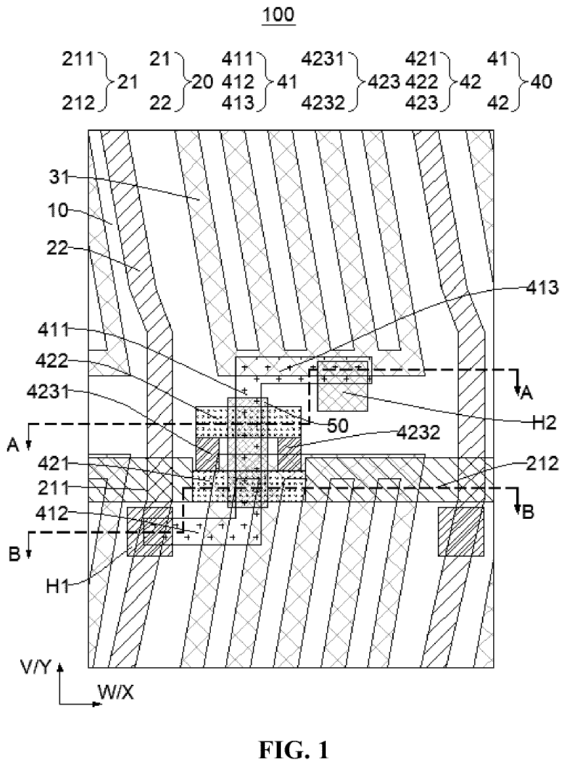

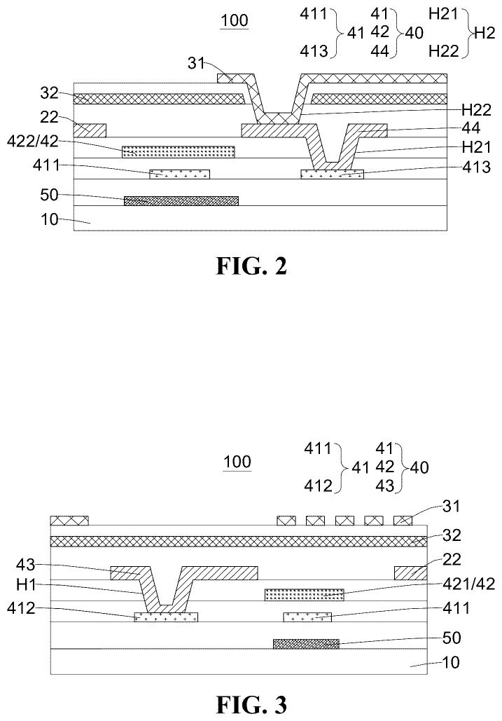

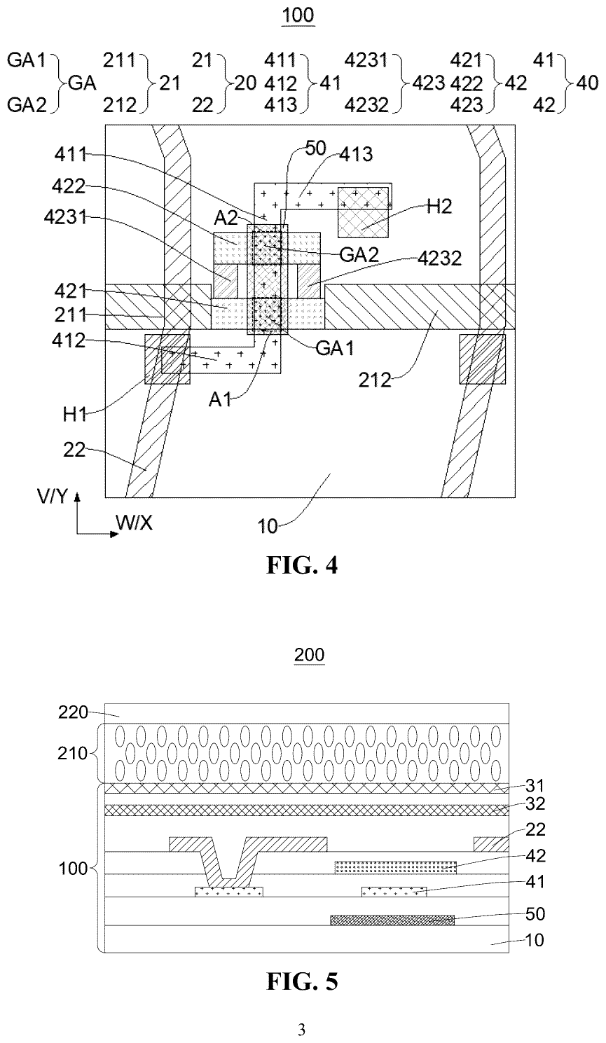

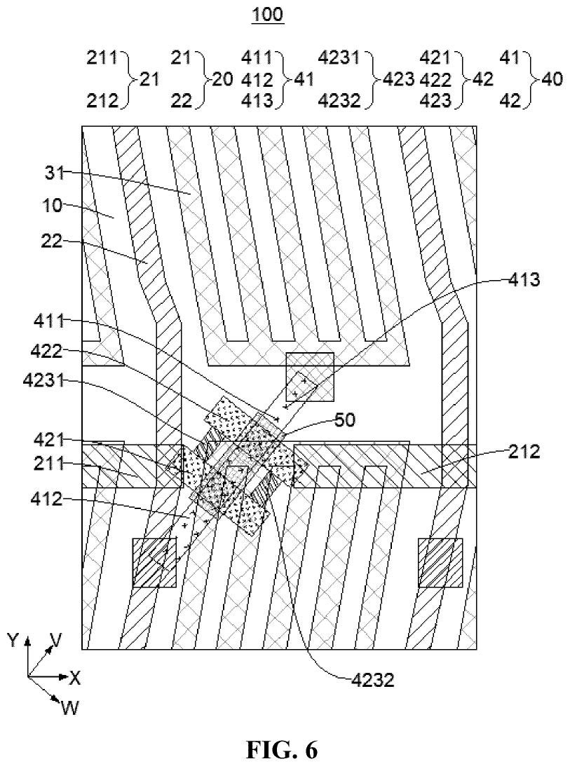

FIG. 1 is a schematic structural diagram of an array substrate according to some embodiments of the present application. FIG. 2 is a schematic structural cross-sectional view of A-A in FIG. 1. FIG. 3 is a schematic structural cross-sectional view of B-B in FIG. 1. FIG. 4 is a schematic structural diagram of another array substrate according to some embodiments of the present application. FIG. 5 is a schematic structural diagram of a display panel according to some embodiments of the present application. FIG. 6 is a schematic structural diagram of another array substrate according to some embodiments of the present application.

In view of this, in a first aspect, as shown in FIG. 1 to FIG. 6, an embodiment of the present application provides an array substrate 100 that includes a substrate 10, routing lines 20, a pixel driving electrode 31 and a thin film transistor 40. The routing lines 20 are arranged on the substrate 10, and the routing lines 20 include a first routing line 21. The pixel driving electrode 31 is arranged on the substrate 10. The thin film transistor 40 is arranged on the substrate 10 and is connected to the routing lines 20 and the pixel driving electrode 31 each, the thin film transistor 40 includes an active layer 41 and a gate 42 that are stacked. The gate 42 is electrically connected to the first routing line 21 and includes a first gate portion 421, a second gate portion 422 and a connecting line 423 which are arranged in the same layer, the connecting line 423 are arranged to intersect with the first routing line 21. The first gate portion 421 and the second gate portion 422 are in a strip-shaped and connected with each other through the connecting line 423. The active layer 41 includes a strip-shaped main portion 411. In a direction perpendicular to the substrate 10, the main portion 411 overlaps with the first gate portion 421 and the second gate portion 422 each to form two channel regions GA.

Optionally, the array substrate 100 may be applied to LCD (Liquid Crystal Display) liquid crystal display panel, OLED (Organic Light-Emitting Diode) organic electric laser display panel, and QLED (Quantum Dot Light Emitting Diodes) quantum dot light emitting diode display panel. The following embodiments are explained by taking the liquid crystal display panel 200 as an example.

Specifically, as shown in FIG. 5, the display panel 200 includes a first substrate and a second substrate 220 arranged opposite to each other. Optionally, the first substrate may be understood as the array substrate 100, and the second substrate 220 may be understood as a color film substrate including a color resistance structure and a black matrix structure. A liquid crystal layer 210 is arranged between the first substrate and the second substrate 220. The liquid crystal layer 210 includes liquid crystal molecules that can include positive liquid crystals and negative liquid crystals. The liquid crystal molecules are parallel to the panel direction when not powered, that is, when no driving electric field is applied. The positive liquid crystal and the negative liquid crystal have different angles. When powered, that is, when a driving electric field is applied, the long axis of the positive liquid crystal molecules deflects along a direction of the electric field, and the long axis of the negative liquid crystal molecules deflects perpendicular to the direction of the electric field, which can be set according to actual needs in specific implementation. Optionally, the driving electric field may be provided by the pixel driving electrode 31 and the common electrode 32.

The substrate 10 mainly plays a supporting and bearing role, and other film layers are stacked on the substrate 10 in sequence. The stacking arrangement mentioned here refers to that: other film layers are arranged in sequence along a thickness direction of the substrate 10. Herein, the substrate 10 may include multiple film layer structures, and the specific film layer structure composition of the substrate 10 is not limited in the embodiments of the present application. In addition, a thickness direction of other film layers located on one side of the substrate 10 and a direction perpendicular to the substrate are usually consistent with a thickness direction of the substrate 10 itself. Therefore, for the convenience of expression, the thickness direction of the substrate 10, the thickness direction of other film layers or the direction perpendicular to the substrate 10 mentioned later in the embodiments of the present application are all indicated in the same direction.

The routing lines 20 are arranged on the substrate 10 and may include multiple different types of routing lines 20. Different types of routing lines 20 may be arranged in the same layer or in different layers. When different types of routing lines 20 are arranged in different layers, two adjacent layers of routing lines 20 are insulated by insulating materials.

The thin film transistor 40 is arranged on the substrate 10 and includes multiple functional film layers. For example, the thin film transistor 40 includes an active layer 41, a gate 42, and a source/drain 44 stacked in sequence in a direction away from the substrate 10. Optionally, the active layer 41 may also be located on one side of the gate 42 facing away from the substrate 10.

In some examples, the shapes and sizes of the first gate portion 421 and the second gate portion 422 are exactly the same, of course, or be different. For example, a size of the first gate portion 421 along its own length direction is different from that of the second gate portion 422 along its own length direction; and/or, a size of the first gate portion 421 along its own width direction is different from that of the second gate portion 422 along its own width direction.

In some examples, an extension direction of the first gate portion 421 and an extension direction of the second gate portion 422 may be parallel, or may intersect with each other.

The first gate portion 421, the second gate portion 422 and the connecting line 423 are arranged in the same layer, that is, the first gate portion 421, the second gate portion 422 and the connecting line 423 may be made by a preparation process. Optionally, the first routing line 21 and the first gate portion 421 are arranged in the same layer. Optionally, the extension directions of the first gate portion 421 and the first routing line 21 may be the same, or may be different. Optionally, the extension directions of the second gate portion 422 and the first routing line 21 may be the same.

Optionally, the shapes and sizes of the connecting line 423 and the first gate portion 421 may be the same, or may be different. Optionally, the first routing line 21 is a scan line. Optionally, the first routing line 21 and the connecting line 423 are arranged vertically.

In the array substrate 100 provided according to the present application, the gate 42 in the thin film transistor 40 is electrically connected to the first routing line 21, and the first routing line 21 provides voltage to the gate 42 to control the switch of the thin film transistor 40. The gate 42 includes a first gate portion 421 and a second gate portion 422. The main portion 411 of the active layer 41 overlaps with the first gate portion 421 and the second gate portion 422 each to form two channel regions GA, so as to reduce the leakage current of the thin film transistor 40. On this basis, the first gate portion 421 and the second gate portion 422 are connected with each other by a connecting line 423, and then the gate 42 and the first routing line 21 are electrically connected to reduce a spacing distance between the first gate portion 421 and the second gate portion 422, reduce an overall size of the thin film transistor 40, and increase an aperture ratio, thereby improving the overall performance of the thin film transistor 40 and improving the display effect.

As shown in FIGS. 1 to 3, in the liquid crystal display panel 200, the array substrate 100 may be stacked with a substrate 10, an active layer 41, a gate 42, a data line, a common electrode 32, and a pixel driving electrode 31 in sequence along the thickness direction. An insulating material is provided between two adjacent layers for being insulated with each other. Optionally, the active layer 41 and the data line are electrically connected through a first via hole H1, and the conductive material formed in the first via hole H1 is a source 43 of the thin film transistor 40; the active layer 41 and the pixel driving electrode 31 are electrically connected through a second via hole H2, and the conductive material formed in the second via hole H2 is a drain 44 of the thin film transistor 40. Optionally, the drain 44 may include two portions, the second via hole H2 between the active layer 41 and the pixel driving electrode 31 includes a first sub-via hole H21 and a second sub-via hole H22, the first sub-via hole H21 penetrates an insulating film layer between the active layer 41 and the data line, the second sub-via hole H22 penetrates an insulating film layer between the data line and the pixel driving electrode 31, a portion of the drain 44 is arranged in the same layer as the data line and is electrically connected to the active layer 41 through the first sub-via hole H21, and another portion of the drain 44 is arranged in the same layer as the pixel driving electrode 31 and is electrically connected to the drain 44 in the same layer as the data line through the second sub-via hole H22, thereby electrically connecting the active layer 41 and the pixel driving electrode 31, so as to reduce the risk of the conductive material in the second via hole H2 being broken due to the second via hole H2 being too deep.

Optionally, the array substrate 100 may also include a scan line, a touch line, and a touch bridge line. Optionally, the scan line may be arranged in the same layer as the gate 42. The touch lines and the touch bridge lines are arranged in the same layer as the data lines and the common electrodes 32, respectively.

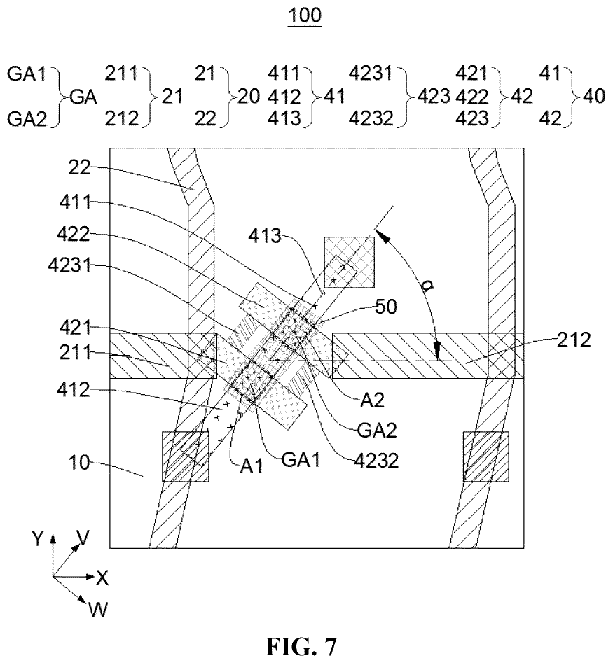

FIG. 7 is a schematic structural diagram of another array substrate according to some embodiments of the present application.

As shown in FIG. 1 to FIG. 4, FIG. 6 and FIG. 7, in some optional embodiments, along a direction perpendicular to the substrate 10, the main portion 411 overlaps with the first gate portion 421 to form a first region A1, and the main portion 411 overlaps with the second gate portion 422 to form a second region A2. The first region A1 and the second region A2 are arranged side by side along a first direction V, and an extension direction of a portion of the first gate portion 421 located in the first region A1 and an extension direction of a portion of the second gate portion 422 located in the second region A2 are both parallel to a second direction W, and the second direction W is perpendicular to the first direction V.

Optionally, a portion of the main portion 411 in the first region A1 forms a channel region GA, for example, the formed channel region GA is a first channel region GA1.

Optionally, a portion of the main portion 411 in the second region A2 forms a channel region GA, for example, the formed channel region GA is a second channel region GA2.

Optionally, the first channel region GA1 and the second channel region GA2 are arranged in parallel along the second direction W.

It can be understood that the shapes of the main portion 411, the first gate portion 421 and the second gate portion 422 are all strip-shaped, the shapes of the first channel region GA1 and the second channel region GA2 are the same, and the sizes may be the same or different. For example, the shapes of the first channel region GA1 and the second channel region GA2 are rectangles, squares or quadrilaterals of other shapes. A rectangular area of the first channel region GA1 may be equal to, greater than or less than a rectangular area of the second channel region GA2.

Optionally, a portion of the first gate portion 421 in the first region A1 is a first overlapping portion, and a portion of the second gate portion 422 in the second region A2 is a second overlapping portion, and the first overlapping portion is parallel to the second direction W along an extension direction of the first gate portion 421. The second overlapping portion is parallel to the second direction W along an extension direction of the second gate portion 422.

It can be understood that the shapes of the first overlapping portion and the second overlapping portion may both be rectangular, square or quadrilaterals of other shapes. Taking a rectangle as an example, the extension direction of the first overlapping portion is also a length direction of the rectangle.

In these optional embodiments, the above-mentioned arrangements are conducive to reducing the shape difference of the two channel regions GA, thereby reducing the characteristic difference of the two channel regions GA, reducing the leakage current of the thin film transistor 40, improving the overall performance of the thin film transistor 40, and thus improving the display effect.

As shown in FIG. 1 to FIG. 4, and FIG. 6 and FIG. 7, in some optional embodiments, the extension direction of the first gate portion 421 and the extension direction of the second gate portion 422 are arranged in parallel, simplifying the arrangement difficulty of the first gate portion 421 and the second gate portion 422, so as to reduce the shape difference, size difference and angle difference between the first channel region GA1 and the second channel region GA2, thereby reducing the characteristic difference between the first channel region GAL and the second channel region GA2, reducing the leakage current of the thin film transistor 40, and improving the overall characteristics of the thin film transistor 40. In addition, the parallel arrangement can also reduce a spacing distance between the first gate portion 421 and the second gate portion 422, and reduce the overall size of the thin film transistor 40.

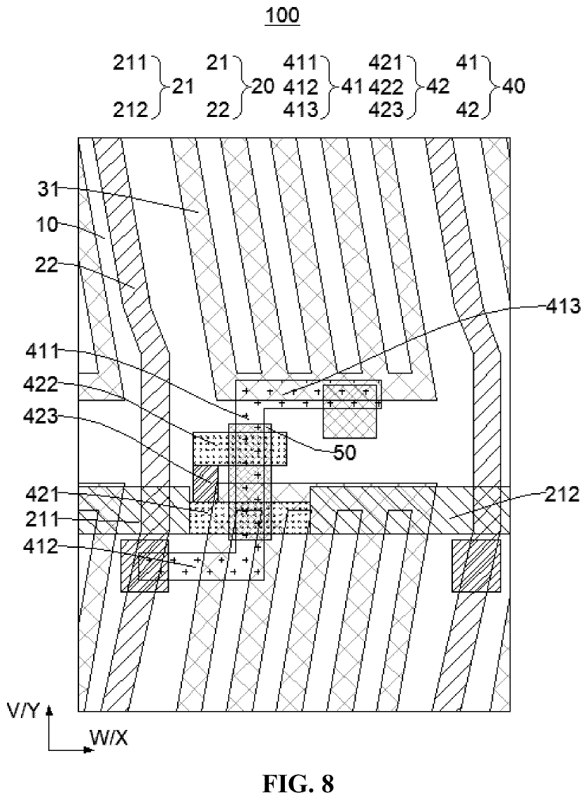

FIG. 8 is a schematic structural diagram of another array substrate according to some embodiments of the present application.

As shown in FIG. 1, FIG. 4 and FIG. 8, in some optional embodiments, the first routing line 21 extends along the third direction X, the extension direction of the first gate portion 421 and the extension direction of the second gate portion 422 are both parallel to the first routing line 21, and the third direction X intersects with the first direction V.

Optionally, multiple first routing lines 21 extends along the third direction X, multiple first routing lines 21 are arranged at intervals along the fourth direction Y, and the third direction X intersects with the fourth direction Y. Optionally, the third direction X and the fourth direction Y are arranged vertically.

Exemplarily, the extension direction of the first gate portion 421 is parallel to the first routing line 21, and the extension direction of the second gate portion 422 is parallel to the first routing line 21.

In these optional embodiments, the arrangement directions of the first gate portion 421, the second gate portion 422 and the first routing line 21 are simplified, the difficulty of preparing the gate 42 and the first routing line 21 is reduced, and the production efficiency is improved.

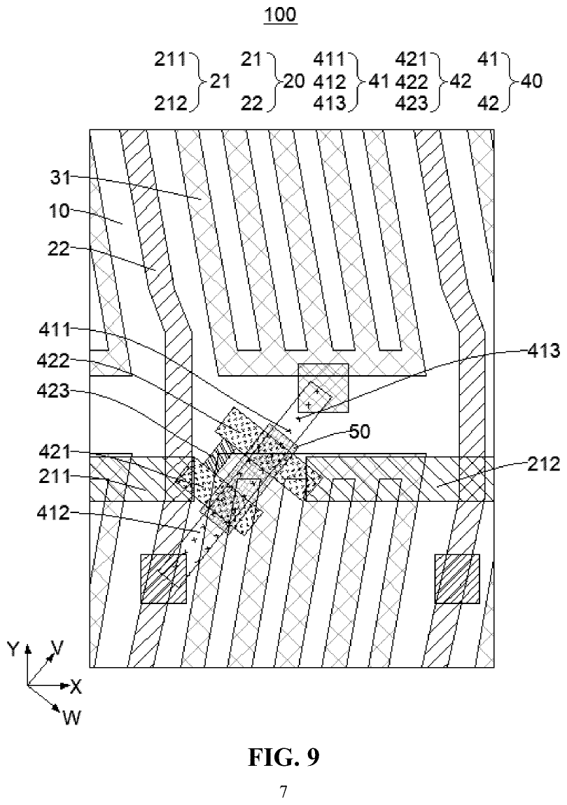

FIG. 9 is a schematic structural diagram of another array substrate according to some embodiments of the present application.

As shown in FIG. 6, FIG. 7 and FIG. 9, in some optional embodiments, the first routing line 21 extends along the third direction X, the extension direction of the first gate portion 421 and the extension direction of the second gate portion 422 are both intersected with the first routing line 21, and the third direction X intersects with the first direction V.

Exemplarily, the extension direction of the first gate portion 421 intersects with the first routing line 21, and the extension direction of the second gate portion 422 intersects with the first routing line 21.

In some examples, the extension direction of the first gate portion 421 is parallel to the extension direction of the second gate portion 422, and an intersection angle between the first gate portion 421 and the first routing line 21 is the same as an intersection angle between the second gate portion 422 and the first routing line 21. In some other examples, the extension direction of the first gate portion 421 and the extension direction of the second gate portion 422 are intersected with each other, and the intersection angle between the first gate portion 421 and the first routing line 21 is different from the intersection angle between the second gate portion 422 and the first routing line 21.

In these optional embodiments, the above-mentioned arrangements are conducive to reducing the space occupied by the first gate portion 421 and the second gate portion 422 in the fourth direction Y, thereby reducing the space occupied by the first channel region GA1 and the second channel region GA2 in the fourth direction Y, and then reducing the size of the thin film transistor 40 in the fourth direction Y, so as to further reduce the overall size of the thin film transistor 40.

As shown in FIGS. 1, 6, 8 and 9, in some optional embodiments, at least one of the first gate portion 421, the second gate portion 422 and the connecting line 423 is electrically connected to the first routing line 21, which is conducive to increasing the connection mode of the electrical connection between the first routing line 21 and the gate 42, thereby improving the application range of the thin film transistor 40.

In some examples, the first routing line 21 is electrically connected to only one of the first gate portion 421, the second gate portion 422 and the connecting line 423. In other examples, any two of the first gate portion 421, the second gate portion 422 and the connecting line 423 are electrically connected to the first routing line 21. In some other examples, the first gate portion 421, the second gate portion 422 and the connecting line 423 are all electrically connected to the first routing line 21.

As shown in FIG. 1 and FIG. 8, in some optional embodiments, the first routing line 21 includes a first portion 211 and a second portion 212, both of which are connected to the first gate portion 421, and the second gate portion 422 is electrically connected to the first gate portion 421 through the connecting line 423.

Exemplarily, each first routing line 21 may be a first portion 211 and a second portion 212 that are disconnected, the first portion 211 and the second portion 212 are electrically connected through the first gate portion 421, and an end of the second gate portion 422 along its own extension direction is electrically connected to an end of the first gate portion 421 along its own extension direction through the connecting line 423. Alternatively, the first portion 211 and the second portion 212 may also be connected with each other.

Optionally, the second gate portion 422 may be electrically connected to the first gate portion 421 through a connecting line 423. Alternatively, the second gate portion 422 can also be electrically connected to the first gate portion 421 through two connecting lines 423, so that the first gate portion 421 and the second gate portion 422 are connected in parallel, thereby reducing the overall resistance of the gate 42.

In these optional embodiments, the first routing line 21 is arranged as a first portion 211 and a second portion 212, which is conductive to reducing the connection difficulty of the first routing line 21 and the gate 42. The first gate portion 421 may be used as routing lines 20 connecting the first portion 211 with the second portion 212, reducing the redundant arrangement of the first routing line 21, thereby simplifying the wiring difficulty of the first routing line 21 and the gate 42, and reducing the wiring space of the first routing line 21 and the gate 42.

As shown in FIG. 4 and FIG. 8, in some optional embodiments, the routing lines 20 include a second routing line 22, and the active layer 41 also includes a first connection portion 412 and a second connection portion 413 that are both connected to the main portion 411, the first connection portion 412 being electrically connected to the second routing line 22, and the second connection portion 413 being electrically connected to the pixel driving electrode 31. An extension direction of the first connection portion 412 and an extension direction of the second connection portion 413 are both arranged to intersect with an extension direction of the main portion 411.

Optionally, multiple second routing lines 22 extends along the fourth direction Y, and multiple second routing lines 22 are arranged at intervals along the third direction X. Optionally, the second routing line 22 may be a data line.

Optionally, the first connection portion 412 may be a source connection region electrically connected to a source 43 of the thin film transistor 40.

Optionally, the second connection portion 413 may be a drain connection region electrically connected to a drain 44 of the thin film transistor 40.

Optionally, the first connection portion 412 and the second connection portion 413 are arranged at two ends of the strip-shaped main portion 411 along its own extension direction respectively.

Optionally, the shapes and sizes of the first connection portion 412 and the second connection portion 413 may be the same, or of course, different. Exemplarily, the first connection portion 412 and the second connection portion 413 are both in a strip-shaped.

Optionally, the extension direction of the first connection portion 412 and the extension direction of the second connection portion 413 are arranged in parallel. Exemplarily, the extension direction of the first connection portion 412 is arranged in parallel with the third direction X. The extension direction of the second connection portion 413 is arranged in parallel with the third direction X. Of course, the extension direction of the first connection portion 412 and the extension direction of the second connection portion 413 may also be intersected with each other.

In some examples, the extension direction of the first connection portion 412 intersects with the extension direction of the main portion 411, and the extension direction of the second connection portion 413 intersects with the extension direction of the main portion 411.

Optionally, the extension direction of the first connection portion 412 is perpendicular to the extension direction of the main portion 411, and the extension direction of the second connection portion 413 is perpendicular to the extension direction of the main portion 411.

Optionally, the extension direction of the first connection portion 412 is arranged in parallel with the extension direction of the first gate portion 421.

Optionally, the extension direction of the second connection portion 413 is arranged in parallel with the extension direction of the second gate portion 422.

Optionally, the first gate portion 421 is located on one side of the second gate portion 422 facing away from the second connection portion 413.

Optionally, the first connection portion 412 and the second connection portion 413 are located on the same side of the main portion 411 along the third direction X.

In the embodiments of the present application, the above-mentioned arrangement is conducive to increasing a distance between the source/drain 44 and the channel region GA, and reducing the risk of damage to the channel region GA during the preparation of the source/drain 44, which would otherwise cause a decrease in the performance of the thin film transistor 40.

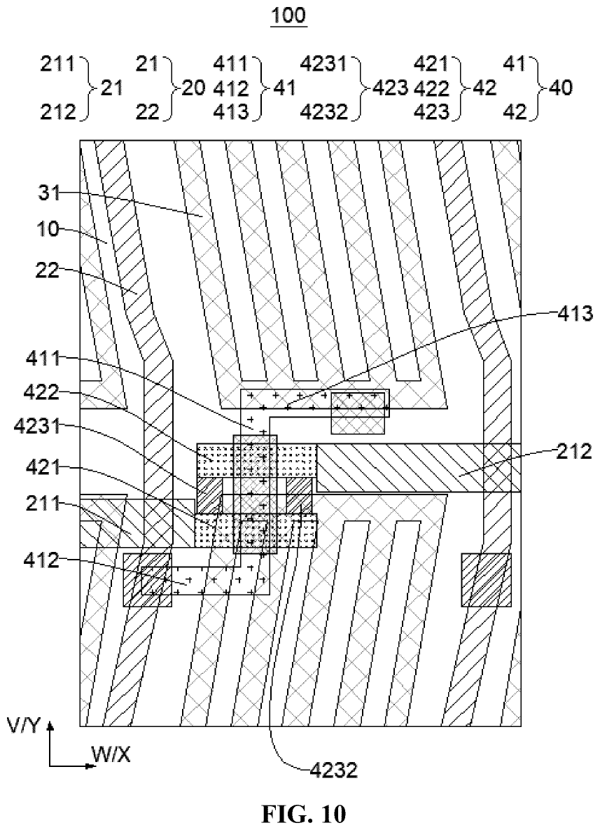

FIG. 10 is a schematic structural diagram of another array substrate according to some embodiments of the present application.

As shown in FIG. 9 and FIG. 10, in some optional embodiments, the first routing line 21 includes a first portion 211 and a second portion 212, the first gate portion 421 is connected to the first portion 211, the second gate portion 422 is connected to the second portion 212, the connecting line 423 includes a first connecting line 4231, and one end of the first gate portion 421 close to the first portion 211 is electrically connected to the second gate portion 422 through the first connecting line 4231, and/or, the connecting line 423 includes a second connecting line 4232, and one end of the second gate portion 422 close to the second portion 212 is electrically connected to the first gate portion 421 through the second connecting line 4232.

In some examples, the first gate portion 421 is electrically connected to the first portion 211, the second gate portion 422 is electrically connected to the second portion 212, and the end of the first gate portion 421 close to the first portion 211 is electrically connected to the second gate portion 422 through the first connecting line 4231.

In some examples, the first gate portion 421 is electrically connected to the first portion 211, the second gate portion 422 is electrically connected to the second portion 212, and one end of the second gate portion 422 close to the second portion 212 is electrically connected to the first gate portion 421 through the second connecting line 4232.

In other examples, the connecting line 423 includes a first connecting line 4231 and a second connecting line 4232, the first connecting line 4231 and the second connecting line 4232 connect the first gate portion 421 and the second gate portion 422 in parallel, and the first gate portion 421 and the second gate portion 422 are connected to the first portion 211 and the second portion 212 of the first routing line 21 respectively, so as to reduce the overall resistance of the gate 42 while connecting the first routing line 21, reduce the redundant arrangement of the first routing line, and reduce the wiring space of the first routing line 21.

As shown in FIGS. 6 and 7, in some optional embodiments, a minimum included angle between the extension direction of the active layer 41 and the first routing line 21 is a, 30°≤α≤90°.

Optionally, the first connection portion 412, the second connection portion 413 and the main portion 411 of the active layer 41 may be in a straight line, and the minimum included angle between the extension direction of the active layer 41 and the first routing line 21, that is, a minimum included angle between the active layer 41 and the third direction X.

Optionally, the minimum included angle α may be 30°, 40°, 45°, 60°, 75°, 80°, 83° or 90°.

In these optional embodiments, the above-mentioned arrangements are conducive to increasing a spacing distance between the source/drain and the first routing line 21, reducing the difficulty of preparing the active layer 41, and improving the production yield.

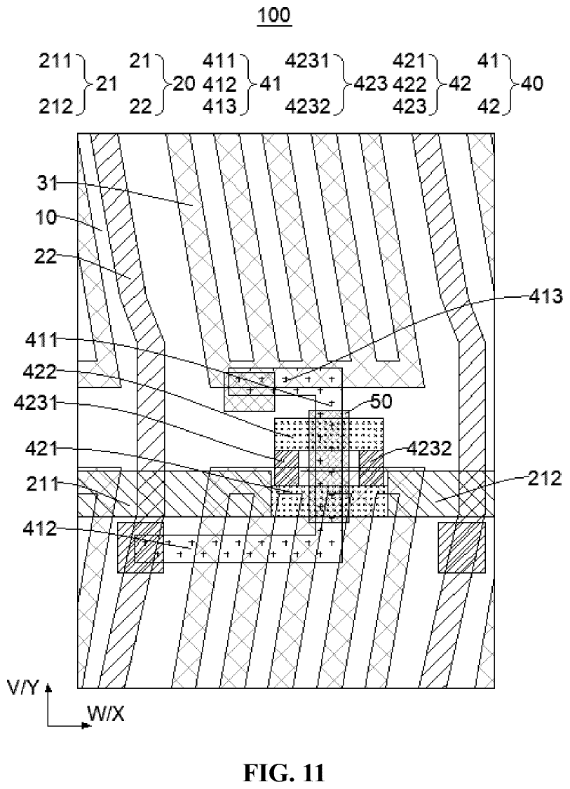

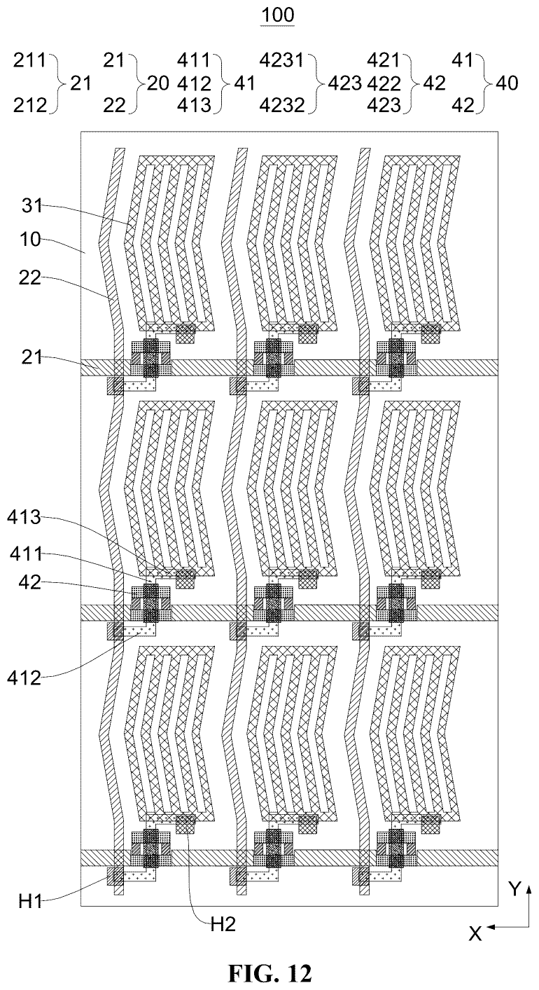

FIG. 11 is a schematic structural diagram of another array substrate according to some embodiments of the present application. FIG. 12 is a schematic structural diagram of another array substrate according to some embodiments of the present application.

As shown in FIG. 8, FIG. 11 and FIG. 12, in some optional embodiments, the routing lines 20 further include a second routing line 22, and the active layer 41 further includes a first connection portion 412 and a second connection portion 413, the first connection portion being electrically connected to the second routing line 22, and the second connection portion 413 being electrically connected to the pixel driving electrode 31. The first routing line 21 extends along the third direction X, the second routing line 22 extends along the fourth direction Y, the first connection portion 412 and the second connection portion 413 are arranged on both sides of the first routing line 21 along the fourth direction Y respectively, and the channel region GA and the second connection portion 413 are arranged at an interval along the third direction X, and the third direction, the fourth direction Y and the direction perpendicular to the substrate 10 intersect with each other.

Exemplarily, as shown in FIG. 12, in the fourth direction Y, the first first routing line 21, the second first routing line 21 and the third first routing line 21 are arranged in sequence. In the thin film transistor 40 electrically connected to the second first routing line 21, the first connection portion 412 is located between the first first routing line 21 and the second first routing line 21, and the second connection portion 413 is located between the second first routing line 21 and the third first routing line 21.

Optionally, the first connection portion 412 and the second connection portion 413 are located on opposite sides of the channel region GA along the third direction X respectively, for example: a shape of the projection of the active layer 41 on the substrate 10 is Z-shaped. Of course, the first connection portion 412 and the second connection portion 413 each are located on the same side of the channel region GA along the third direction X, for example: a shape of the projection of the active layer 41 on the substrate 10 is a rectangle with one side opening.

Optionally, the channel region GA and the first connection portion 412 are arranged at an interval along the third direction X.

In these optional embodiments, the channel region GA and the second connection portion 413 are arranged at an interval along the third direction X to increase the spacing distance between the channel region GA and the second connection portion 413, thereby reducing the risk of damage to the channel region GA in the preparation process of the source/drain, which would otherwise cause a decrease in the performance of the thin film transistor 40. In addition, the first connection portion 412 and the second connection portion 413 are arranged on both sides of the first routing line 21 respectively, which is conducive to reducing the possibility of mutual interference between the source 43 via hole and the drain 44 via hole, thereby improving the production yield.

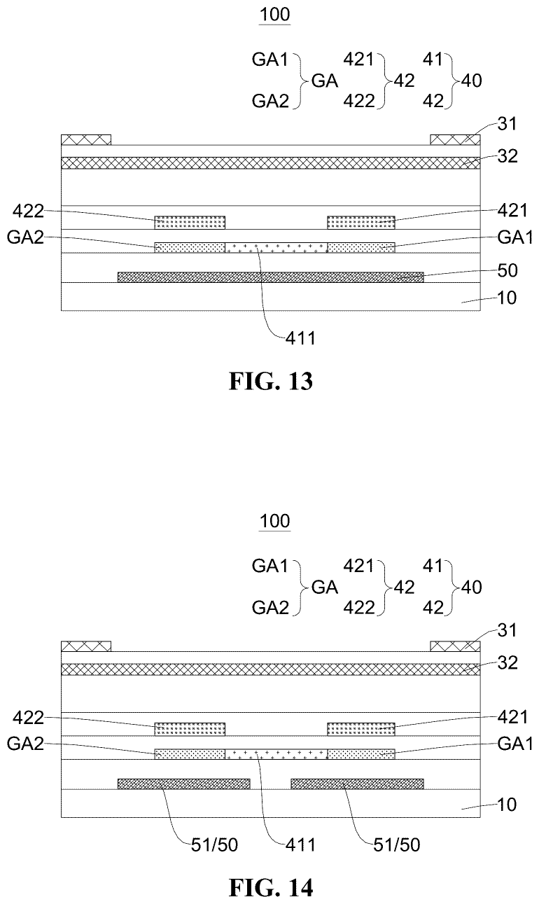

FIG. 13 is a schematic structural cross-sectional view of an array substrate according to some embodiments of the present application. FIG. 14 is a schematic structural cross-sectional view of another array substrate according to some embodiments of the present application.

As shown in FIGS. 13 and 14, in some optional embodiments, the thin film transistor 40 further includes a light shielding layer 50, which is located between the substrate and the active layer 41, and projections of the two channel regions GA along a direction perpendicular to the substrate are both located within a projection of the light shielding layer 50 along the direction perpendicular to the substrate.

In some embodiments, as shown in FIG. 13, the light shielding layer 50 may be a whole, and the projections of the two channel regions GA along the direction perpendicular to the substrate are both located within the projection of the light shielding layer 50 along the direction perpendicular to the substrate.

In some embodiments, as shown in FIG. 14, the light shielding layer 50 includes two light shielding sub-portions, and the two light shielding sub-portions and the two channel regions GA are arranged in a one-to-one correspondence. That is, the projection of a channel region GA in the direction perpendicular to the substrate is located within the projection of a light shielding sub-portion in the direction perpendicular to the substrate.

In these optional embodiments, the light shielding layer 50 can reduce the possibility of the substrate 10 reflecting or irradiating the channel region GA from the direction of incidence of the substrate, thereby reducing the risk of damage to the channel region GA caused by light, and improving the reliability of the thin film transistor 40.

As shown in FIG. 8 and FIG. 9, in some optional embodiments, the extension size of the first gate portion 421 along its own length direction is different from the extension size of the second gate portion 422 along its own length direction.

Optionally, the extension size of the first gate portion 421 along its own length direction is greater than or less than the extension size of the second gate portion 422 along its own length direction.

Exemplarily, the first gate portion 421 and the second gate portion 422 are electrically connected via a connecting line 423, the ends of the first gate portion 421 and the second gate portion 422 connected to the connecting line 423 are flush with each other, and the end of the second gate portion 422 not connected to the connecting line 423 extends beyond the end of the first gate portion 421 connected to the connecting line 423.

The above-mentioned arrangement of the embodiment of the present application is conducive to reducing the redundant arrangement of the first gate portion 421 or the second gate portion 422, thereby reducing the wiring space of the gate 42.

As shown in FIG. 10, in some optional embodiments, the extension direction of the first gate portion 421 and the extension direction of the second gate portion 422 are both arranged perpendicular to the extension direction of the main portion 411, so as to reduce the characteristic difference between the two channel regions GA, simplify the arrangement difficulty of the gate 42, and improve the overall performance of the thin film transistor 40.

Optionally, in the first region A1, the first overlapping portion of the first gate portion 421 is arranged perpendicularly along the extension direction of the first gate portion and the extension direction of the main portion 411.

Optionally, in the second region A2, the second overlapping portion of the second gate portion 422 is arranged perpendicularly along the extension direction of the second gate portion and the extension direction of the main portion 411.

As shown in FIG. 4 and FIG. 7, in some optional embodiments, the width of the first gate portion 421 and the width of the second gate portion 422 are equal, further reducing the size difference between the two channel regions GA, reducing the characteristic difference between the two channel regions GA, and improving the overall performance of the thin film transistor 40.

Exemplarily, the width of the first overlapping portion of the first gate portion 421 is equal to the width of the second overlapping portion of the second gate portion 422.

As shown in FIG. 5, in the second aspect, an embodiment of the present application further provides a display panel 200, including any array substrate 100 as described above.

Since the display panel provided in the embodiments of the present application includes the array substrate of any of the above embodiments, the display panel provided in the embodiments of the present application has the beneficial effects of the array substrate of any of the above embodiments, which will not be described in detail here.

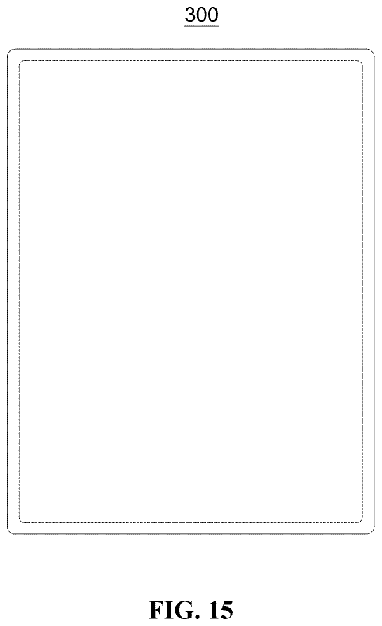

As shown in FIG. 15, in the third aspect, an embodiment of the present application further provides a display device 300, including any display panel 200 as described above.

Although the present application has been described with reference to the preferred embodiments, various improvements may be performed thereto and components thereof may be replaced with equivalents without departing from the scope of the present application. In particular, as long as there is no structural conflict, the various technical features mentioned in each embodiment may be combined in any manner. The present application is not limited to the specific embodiments disclosed herein, but includes all technical solutions falling within the scope of the claims.

What is claimed is:

1. An array substrate, comprising:
a substrate;
routing lines arranged on the substrate, wherein the routing lines comprise a first routing line;
a pixel driving electrode arranged on the substrate; and
a thin film transistor arranged on the substrate and connected to the routing lines and the pixel driving electrode, wherein the thin film transistor comprises an active layer and a gate that are stacked, the gate is electrically connected to the first routing line and comprises a first gate portion, a second gate portion and a connecting line arranged in a same layer, the connecting line intersecting with the first routing line, the first gate portion and the second gate portion being in a strip-shaped and connected with each other through the connecting line, and the active layer comprises a strip-shaped main portion overlapping with the first gate portion and the second gate portion each along a direction perpendicular to the substrate to form two channel regions.

2. The array substrate according to claim 1, wherein along the direction perpendicular to the substrate, the main portion overlaps with the first gate portion to form a first region and the second gate portion to form a second region, the first region and the second region being arranged side by side along a first direction, and an extension direction of a portion of the first gate portion located in the first region and an extension direction of a portion of the second gate portion located in the second region are both parallel to a second direction, and the second direction being perpendicular to the first direction.

3. The array substrate according to claim 2, wherein an extension direction of the first gate portion and an extension direction of the second gate portion are arranged in parallel.

4. The array substrate according to claim 3, wherein the first routing line extends along a third direction, the extension direction of the first gate portion and the extension direction of the second gate portion are both arranged parallel to the first routing line, and the third direction intersects with the first direction.

5. The array substrate according to claim 3, wherein the first routing line extends along a third direction, the extension direction of the first gate portion and the extension direction of the second gate portion are both arranged to intersect with the first routing line, and the third direction intersects with the first direction.

6. The array substrate according to claim 1, wherein at least one of the first gate portion, the second gate portion and the connecting line is electrically connected to the first routing line.

7. The array substrate according to claim 6, wherein the first routing line comprises a first portion and a second portion both connected to the first gate portion, and the second gate portion is electrically connected to the first gate portion through the connecting line.

8. The array substrate according to claim 7, wherein the routing lines further comprise a second routing line, the active layer further comprises a first connection portion and a second connection portion that are both connected to the main portion, the first connection portion being electrically connected to the second routing line, and the second connection portion being electrically connected to the pixel driving electrode; and
an extension direction of the first connection portion and an extension direction of the second connection portion are both arranged to intersect with an extension direction of the main portion.

9. The array substrate according to claim 6, wherein the first routing line comprises a first portion and a second portion, the first gate portion is connected to the first portion, the second gate portion is connected to the second portion, and the connecting line comprises a first connecting line, and an end of the first gate portion close to the first portion is electrically connected to the second gate portion through the first connecting line, and/or,
the connecting line comprises a second connecting line, and an end of the second gate portion close to the second portion is electrically connected to the first gate portion through the second connecting line.

10. The array substrate according to claim 9, wherein a minimum included angle between an extension direction of the active layer and the first routing line is a, 30°≤α≤90°.

11. The array substrate according to claim 1, wherein the routing lines further comprise a second routing line, the active layer further comprises a first connection portion and a second connection portion, the first connection portion being electrically connected to the second routing line, and the second connection portion being electrically connected to the pixel driving electrode; and
the first routing line extends along a third direction, the second routing line extends along a fourth direction, the first connection portion and the second connection portion are arranged on both sides of the first routing line along the fourth direction respectively, and the channel region and the second connection portion are arranged at an interval along the third direction, and the third direction, the fourth direction and a direction perpendicular to the substrate intersect with each other.

12. The array substrate according to claim 1, wherein the thin film transistor further comprises a light shielding layer located between the substrate and the active layer, and projections of the two channel regions along a direction perpendicular to the substrate are both located within a projection of the light shielding layer along the direction perpendicular to the substrate.

13. The array substrate according to claim 1, wherein an extension size of the first gate portion in a direction of a length of the first gate portion is different from an extension size of the second gate portion in a direction of a length of the second gate portion.

14. The array substrate according to claim 1, wherein an extension direction of the first gate portion and an extension direction of the second gate portion are both perpendicular to an extension direction of the main portion.

15. The array substrate according to claim 1, wherein a width of the first gate portion and a width of the second gate portion are equal.

16. A display panel, comprising: an array substrate comprising:
a substrate;
routing lines arranged on the substrate, wherein the routing lines comprise a first routing line;
a pixel driving electrode arranged on the substrate; and
a thin film transistor arranged on the substrate and connected to the routing lines and the pixel driving electrode, wherein the thin film transistor comprises an active layer and a gate that are stacked, the gate is electrically connected to the first routing line and comprises a first gate portion, a second gate portion and a connecting line arranged in a same layer, the connecting line intersecting with the first routing line, the first gate portion and the second gate portion being in a strip-shaped and connected with each other through the connecting line, and the active layer comprises a strip-shaped main portion overlapping with the first gate portion and the second gate portion each along a direction perpendicular to the substrate to form two channel regions.

17. A display device, comprising: a display panel comprising an array substrate comprising:
a substrate;
routing lines arranged on the substrate, wherein the routing lines comprise a first routing line;
a pixel driving electrode arranged on the substrate; and
a thin film transistor arranged on the substrate and connected to the routing lines and the pixel driving electrode, wherein the thin film transistor comprises an active layer and a gate that are stacked, the gate is electrically connected to the first routing line and comprises a first gate portion, a second gate portion and a connecting line arranged in a same layer, the connecting line intersecting with the first routing line, the first gate portion and the second gate portion being in a strip-shaped and connected with each other through the connecting line, and the active layer comprises a strip-shaped main portion overlapping with the first gate portion and the second gate portion each along a direction perpendicular to the substrate to form two channel regions.
